(19) United States
(12) Patent Application Publication
(10) Pub. No.: US 2026/0229878 A1
(43) Pub. Date: Aug. 6, 2026

(54) PV ENERGY GENERATION PLANT WITH CENTRAL INVERTER

(71) Applicant: SMA Solar Technology AG, Niestetal (DE)

(72) Inventor: Andreas Falk, Kassel (DE)

(21) Appl. No.: 19/576,432

(22) Filed: Mar. 24, 2026

Related U.S. Application Data
(63) Continuation of application No. PCT/EP2024/076726, filed on Sep. 24, 2024.

(30) Foreign Application Priority Data
Sep. 26, 2023 (DE) 10 2023 126 151.7

(51) Int. Cl. H02H 7/20; G01R 19/10; G01R 19/165; G01R 31/52; H02J 3/001; H02J 3/38; H02J 13/12; H02J 101/24; H02S 50/10

(52) U.S. Cl. CPC H02H 7/20; G01R 19/10; G01R 19/16571; G01R 31/52; H02J 3/00125; H02J 3/38; H02J 13/12; H02S 50/10; H02J 2101/24

(57) ABSTRACT

The application describes a PV energy generation plant with a central inverter circuit connected to a PV generator that comprises a plurality of parallel PV main strings connected, on the input side, to the central inverter circuit via DC lines assigned to a respective PV main string and a monitoring circuit, comprising a differential current measurement circuit, an isolating switch, and a monitoring controller configured to switch the isolating switch after a differential current threshold value I_{S,Diff} has been exceeded and isolate the PV main string. A ground fault monitoring circuit is arranged between a DC link circuit and a grounding connection and comprises a ground current measurement circuit, an isolating circuit, and a controller configured to selectively trip the isolating circuit after a defined delay time T

### REFERENCE TO RELATED APPLICATIONS

This application is a Continuation of International Application number PCT/EP 2024/076726, filed on Sep. 24, 2024, which claims the benefit of German Application number 10 2023 126 151.7, filed on Sep. 26, 2023. The contents of the above-referenced Patent Applications are hereby incorporated by reference in their entirety.

### FIELD

The disclosure relates to a PV energy generation plant with a central inverter unit which comprises a DC/AC converter that can not only feed energy into an alternating voltage grid (AC grid), but also extract energy from the AC grid. Specifically, the PV energy generation plant can be monitored for possible ground faults, wherein it has an isolating device for the DC-side energy source, for example, a photovoltaic generator. The disclosure further relates to a method for monitoring fault currents of such a PV energy generation plant and for isolating the DC-side energy source.

### BACKGROUND

PV energy generation plants are opening up an ever wider range of application possibilities in the context of large-scale plants. In addition to private, home-based energy production, i.e., the conversion of DC voltage provided by PV generators into AC grid voltage by means of an inverter and supplying a household grid or feeding into a public grid, PV power plants in increasingly larger power classes as large-scale power plants are assuming a significant share of the public electricity supply.

A PV plant can comprise a large number of electrical components, for example, PV modules, which are distributed in a decentralized manner over a large area. A group of PV modules grouped as a string, i.e., in the form of a series circuit, is also called a PV string. A PV generator of a PV plant can comprise one or more PV sub-generators or main strings, which consist of a plurality of PV strings that are connected in parallel to one another by means of a connecting device, also called a combiner box, if applicable in each case via a separate DC/DC converter, to a common direct current link circuit (DC link circuit) of a PV inverter or, depending upon the application, to another power converter unit, such as a DC/DC converter. Each of the PV sub-generators can comprise one or more PV strings connected in parallel to one another. For design-related reasons, the PV modules of a PV installation always have an electrical capacitance in relation to their surroundings, for example, in relation to their usually grounded mounting system. This capacitance is not absolutely necessary for the function of the PV plant, but does inevitably result from the mechanical design of the PV modules. It is for this reason often referred to as “parasitic capacitance” or “discharge capacitance.” The parasitic capacitance of the PV plant usually increases with the size of the PV generator assigned thereto, which is why a powerful PV generator also has a correspondingly large parasitic capacitance. In addition, the parasitic capacitance is dependent upon ambient conditions and, for example, increases further during rain due to an associated moist surface of the PV modules and/or due to a dielectric constant of the air that changed on account of increased humidity.

Due to the parasitic capacitance of the PV modules with respect to the ground potential, normal operation of the PV plant always results in a more or less strong discharge current from the PV generator toward the ground potential.

If, due to a fault, e.g., a defective line insulation, a grounded person now comes into contact with an energized component of the PV generator, e.g., the defective line, an additional fault current toward the ground potential will result, usually abruptly, due to direct contact. Since a fault current starting at a value of approximately 30 mA can endanger personal safety and, starting at a value of approximately 300 mA, becomes relevant to fire protection, it is a regulatory requirement in freely accessible PV plants—but not in closed electrical operating areas—to identify such a fault current reliably and to initiate further measures—for example, a shutdown and/or short-circuiting of the PV generator, in particular of the relevant PV sub-generator, when such a fault current is detected. As a rule, two criteria must be met. On the one hand, the fault current must not have any jumps, i.e., no rapid increases above a comparatively low limit value of, for example, 30 mA, in order to ensure maximum personal protection. On the other hand, for reasons of fire protection and system protection, a total differential current, or capacitive discharge current, occurring overall and measured via the connection lines of a PV generator, must not exceed a significantly higher limit value of several hundred mA.

Due to the ever increasing nominal outputs of PV plants, the parasitic capacitances of the assigned PV generators or PV sub-generators are also rising and thus also the capacitive discharge currents always present in normal operation of the PV plant. However, the threshold value of, for example, 300 mA assigned to the discharge current remains constant, but can still if necessary be reduced due to stricter normative constraints. For this reason, any fault current that may be present can be significantly smaller compared to the always present capacitive discharge current of the PV plant. The detection of the fault current is therefore becoming increasingly complex and expensive due to the low signal-to-noise ratio and the associated measuring systems that require a sensitive design. It is therefore desirable, for example, also in the case of larger PV plants, to be able to detect a potentially occurring fault current reliably and nevertheless cost-effectively, for example, if the potentially occurring fault current is small compared to the capacitive discharge current always present in normal operation of the PV plant.

The problem is that the parasitic capacitance of a PV field connected to a central DC link circuit of a power converter unit, such as a central inverter, is so large that a human or animal can be harmed by the large discharge current that occurs when the entire capacitance is discharged through its body when touching one pole of the PV array, due to an insulation fault.

In the case of particularly large PV fields, a parallel connection is effected by interconnecting individual PV generators to form PV strings, which are in turn combined in connecting units to form sub-generators or “main strings,” and the currents from a plurality of these connecting units are then combined in a DC collection unit, such as a DC busbar or a common DC link circuit, before being fed to a power converter unit, such as an inverter or a DC/DC converter. Insulation monitoring is always carried out, which monitors the ground current and sometimes also comprises a fault isolation device (GFDI—“ground fault detection and interruption”) in order to monitor the PV generator and be able to isolate it if necessary.

With regard to ground faults, normative requirements, such as IEC 63112, stipulate that PV energy generation plants above a certain power class either must be operated behind a fence in an electrical operating area or, if they are publicly accessible, must be equipped with a so-called ground fault monitoring and safety shutdown that meets the aforementioned criteria.

In the prior art, insulation monitoring always takes place, which performs ground current monitoring and also comprises a fault isolation device (GFDI—“ground fault detection and interruption”) in order to monitor the entire PV generator and be able to disconnect it from the central inverter unit if necessary. A GFDI is provided which trips when a tripping current is exceeded in accordance with a tripping characteristic. The tripping time depends only upon the current level caused by a ground fault.

### SUMMARY

The disclosure is directed to providing a PV energy generation plant that offers improved fault current monitoring even with high electrical power and correspondingly large capacity of connected PV generators, and that ensures that large PV energy generation plants can be operated even without a surrounding safety fence.

The energy generation plant according to the disclosure comprises a central inverter unit or circuit and a PV generator for connection to the central inverter unit, wherein the PV generator comprises a plurality of PV main strings which are connected in parallel and are connected, on the input side, to the central inverter unit of the PV energy generation plant via DC lines in each case, and are connected to an alternating voltage grid on the output side via a DC link circuit. The PV generator also comprises a DC/AC converter, an AC isolating switch, a transformer, and a grid connection device, wherein each pair of DC lines assigned to a PV main string is assigned a monitoring unit or circuit, comprising a differential current measurement device or circuit, an isolating switch, and a monitoring controller. The monitoring controller is configured to open the isolating switch within a reaction time T_{R}, after it has been detected that a differential current threshold value I_{S,Diff} Diff has been exceeded, in order to isolate the PV main string. A ground fault monitoring apparatus or circuit is arranged between a pole of the intermediate circuit and a grounding connection, wherein the ground fault monitoring apparatus comprises a ground current measurement device or circuit, an isolating element, and a controller, wherein the controller of the ground fault monitoring apparatus is configured to trip the isolating element after a defined delay time T, after a ground fault has been detected by virtue of a ground current threshold value I_{S} being exceeded, when the ground fault persists after elapse of the delay time T, wherein the delay time T is selected to be greater than the reaction time T_{R}.

The monitoring units, which are assigned to the individual PV main strings in order to monitor them separately, perform monitoring via differential current measurement of the DC lines of the individual PV sub-generators. The differential current measurement devices assigned to the sub-generators can thus detect a difference between an input current into a sub-generator and a return current from the sub-generator that flows to ground via a fault location on the affected sub-generator. This return current path is provided via the grounding connection. The monitoring unit described, which comprises a differential current measurement device or circuit, an isolating switch, and a monitoring controller, is also called an RCD (“residual current detection and interruption”). The term RCD is also used synonymously for the monitoring unit assembly.

The isolation by means of the isolating switch of the monitoring unit after fault detection by the differential current measurement device is tripped without delay after a defined differential current threshold value I_{S,Diff} Diff is exceeded, wherein “without delay” means that the tripping occurs within a reaction time T_{R}, which for technical reasons cannot be exactly zero, of course. This makes it possible, on the one hand, to comply with regulatory requirements regarding a permissible fault current, e.g., in terms of its absolute value or the dynamics of a rapid change, and, on the other, to prevent tripping from already occurring in the case of small currents introduced via the parasitic capacitances of the non-faulty sub-generators.

The aim is to ensure that only the RCD of the faulty sub-generator trips and isolates it, while all other, non-faulty, sub-generators can remain functionally connected.

Since all discharge currents from all sub-generators, as well as the fault-induced ground currents from faulty sub-generators, flow together via the grounding connection and also through the ground fault monitoring apparatus (GFDI), these would trip the GFDI or its isolating element, which would lead to a disconnection or safety shutdown of the entire PV generator, i.e., also of all non-faulty sub-generators. The GFDI provides a grounding connection for normal operation.

For this reason, the GFDI according to the disclosure is provided with a time-delayed tripping mechanism. If the measured ground current exceeds a defined ground current threshold value I_{S}, the controller of the GFDI causes the isolating element to trip only after a certain delay time T. The isolating element can be designed as a ground fault switch. During the period until the GFDI is tripped, the corresponding monitoring unit of a faulty sub-generator can detect a local fault current through the associated differential current measurement device and trigger an isolation without delay using the associated isolating switch. If the only fault lies within the isolated sub-generator, the measured ground current of the GFDI normalizes, and the isolating element (ground fault switch) will not trip if the ground current threshold value I_{S} is not reached. If the fault is not solely due to the isolated sub-generator, or if the fault originated elsewhere, e.g., through damage to the housing or cable routing, and thus no RCD of a sub-generator trips, the isolating element (ground fault switch) will be tripped after elapse of the delay time T.

An energy generation plant according to the disclosure is in one embodiment formed by a photovoltaic energy generation plant that has a plurality of PV main strings which are connected in parallel. These are connected via DC lines to a DC link circuit—for example, a DC bus line or busbar of the central inverter unit. The central inverter unit can be implemented differently depending upon the application. In this way, the central inverter unit can be formed by a DC/AC central inverter, which is configured to convert the energy supplied from the DC energy source, such as the PV generators, and feed it into an alternating voltage grid (AC grid) and/or also to draw energy from the AC grid. The inverter can be single-stage or multi-stage; for example, it can comprise additional DC/AC or DC/DC converter stages. In order to provide a return current path and monitoring, the grounding connection must be arranged on the DC side between the power converter and the monitoring units of the sub-generators on the DC link circuit or the DC busbars. The GFDI and the grounding connection are present at at least one pole of the DC link circuit so that the effect according to the disclosure can occur. Depending upon the type of central inverter unit, this can be located at a positive pole, a negative pole, or at an intermediate potential—for example, at a common center point.

Advantageous embodiments of the disclosure are specified in the following description and the claims, the features of which can be applied individually and in any desired combination with one another.

In one embodiment of the PV energy generation plant according to the disclosure, the delay time T is 50 ms to 500 ms. In one embodiment, the duration of the delay time T is selected depending upon the ground current measured by the ground current measurement device. Thus, different delay times T can be preferably assigned to different value ranges of a measured ground current. Accordingly, different ground current threshold values I_{S} can be defined which each trigger a different delay time T when the measured ground current is exceeded. In this context, it is advantageous to set a long delay time T for a measured ground current that is only just above the smallest ground current threshold value I_{S,MIN}. This can be in the range of minutes, for example. In the event of higher measured ground currents, or when further higher ground current threshold values I_{S} are exceeded, it is advantageous to select a shorter delay time T in order to reduce or avoid damage to the plant caused by the unwanted current flow. The exact dimensioning of the ground current threshold values I_{S} and of the delay time T must be individually adapted to the specific conditions of the PV plant.

In one embodiment of the PV plant according to the disclosure, a maximum ground current threshold value I_{S,MAX} is defined, exceeding which the delay time T is set to zero. In this way, it is possible to react without delay to serious faults that require a complete shutdown to protect the plant. In one embodiment, a maximum ground current threshold value I_{S,MAX} can be over 30 A in order to enable safe operation in accordance with standards.

In one embodiment of the PV plant according to the disclosure, the only ground current threshold value I_{S} or, in the case of multiple ground current threshold values, the minimum ground current threshold value I_{S,MIN} of the ground fault monitoring apparatus is greater than or equal to 1 A. A delay time T is only triggered above this value.

For monitoring the individual sub-generators, it is advantageous that the differential current threshold value I_{S,Diff} of the associated monitoring unit is less than or equal to 300 mA. In this way, international standardized fire protection regulations are met. Furthermore, it is advantageous that the differential current threshold value I_{S,Diff} can be monitored for sudden changes in the range from 30 to 150 mA, in accordance with standard IEC 62109-2 or IEC 63112. The exact requirements for this are set out in the respective standards under the heading “sudden change,”which can be regarded as disclosed in their respective valid versions.

As a rule, the differential current threshold values I_{S,Diff} of the measured differential currents I_{Diff} are smaller than the ground current threshold values I_{S} of the measured (total) ground current I_{E}, since the sum of all discharge currents of the individual sub-generators is included in the measurement of the ground current I_{E} by the ground fault monitoring apparatus, while the monitoring units of the individual main strings/sub-generators only consider the differential currents I_{Diff} between the partial currents flowing into and out of the sub-generator, which ideally (without parasitic discharges) are even close to zero, regardless of the total current strength.

In one embodiment, the ground fault monitoring apparatus has an overcurrent protection device. The overcurrent protection device comprises, in one embodiment, a damping resistor. In this way, damage to the components of the ground fault monitoring apparatus can be avoided, which may be caused by the increased current flow that occurs during the delay time T.

In one embodiment, the damping resistance is smaller than the total resistance of the PV generator, for example, less than 10%, for example, less than 1% of the total resistance of the PV generator. This advantageously ensures that the damping resistance has only a minor influence on the total resistance of the PV plant, thus preventing interference. Furthermore, the influence on the modulation of the central inverter is reduced.

For the purpose of operating a previously described PV energy generation plant in compliance with standards, a fuse connected in series with the GFDI is provided for redundancy reasons. To protect this, the damping resistor acts as an overcurrent protection device, depending upon the desired delay time T. The energy input into the fuse increases quadratically with the current. For example, a 12 Ohm damping resistor allows for a four times longer delay time T compared to a 6 Ohm damping resistor with the same load on the current-carrying components of the GFDI.

In one embodiment, the central inverter unit is advantageously configured to be operated with a stable modulation that does not impose any clock-frequency common-mode voltages to ground on the AC voltage. By avoiding clock-frequency common-mode voltages, feedback to the measured discharge currents of the sub-generators is avoided, thus increasing the measurement accuracy.

In one embodiment, the monitoring units are arranged on DC lines that are arranged within a housing of the central inverter unit and are thus part of the central inverter unit.

In an alternative embodiment, the monitoring units are part of a connecting device that are assigned to each main string, and that connect a plurality of PV strings to form a main string, wherein the connecting device (also referred to as a combiner box) is arranged outside a housing of the central inverter unit. This decentralized arrangement is particularly advantageous for large plants with a large number of main strings, or for a simplified expansion of the plant or interchangeability of the individual components.

Another aspect of the disclosure relates to a method for monitoring fault currents of a previously described PV energy generation plant having a central inverter unit and monitoring units which are assigned to each pair of DC lines assigned to a PV main string (PVn), and a ground fault monitoring apparatus (GFDI) arranged between a pole of an DC link circuit of the central inverter unit and a grounding connection.

The monitoring unit comprises a differential current measurement device, an isolating switch, and a monitoring controller, wherein the monitoring controller continuously monitors a differential current I_{Diff} by means of the differential current measurement device, wherein a differential current fault is detected when a differential current threshold value I_{S,Diff} is exceeded.

The ground fault monitoring apparatus comprises a ground current measurement device, an isolating element, and a controller, wherein the controller monitors a ground current I_{E} by means of the ground current measurement device, wherein a ground fault is detected when a ground current threshold value I_{S} is exceeded, wherein
after the ground fault monitoring apparatus detects a ground fault, tripping of its associated isolating element is delayed by a defined delay time T,
after detecting a differential current fault, the monitoring controller of the monitoring unit opens the isolating switch within a reaction time T_{R}, and
the ground fault monitoring apparatus trips the isolating element only if the ground fault persists after the defined delay time T, wherein the delay time T is selected to be greater than a reaction time T_{R} of the monitoring unit.

Advantageous developments of the disclosure result from the claims, the description, and the drawings. The advantages of features and combinations of several features mentioned in the description are merely exemplary and may take effect alternatively or cumulatively without the advantages necessarily being achieved by embodiments according to the disclosure. Without altering the subject matter of the appended claims, the following applies with regard to the disclosure content of the original application documents and the patent: further features can be found in the drawings—in particular, the relative arrangement and operative connection of a plurality of components. The combination of features of different embodiments of the disclosure or of features of different claims is also possible in deviation from the selected back-references in the claims and is hereby encouraged. This also applies to features that are shown in separate drawings or are mentioned in the description thereof. These features can also be combined with features of different claims. Likewise, features listed in the claims may be omitted for further embodiments of the disclosure.

The features mentioned in the claims and the description are to be understood with respect to their number in such a way that exactly this number or a larger number than the number mentioned is present, without requiring an explicit use of the adverb “at least.” So, for example, when an element is mentioned, this is to be understood as meaning that exactly one element, two elements, or more elements are present. These features can be supplemented by other features or can be the only features of which the product in question consists.

The reference signs contained in the claims do not constitute a limitation of the scope of the subject matter protected by the claims. They merely serve the purpose of making the claims easier to understand.

### BRIEF DESCRIPTION OF THE FIGURES

The disclosure is illustrated below with the aid of figures. In the figures:

FIG. 1 shows an embodiment of a PV energy generation plant according to the disclosure;

FIG. 2 shows a schematic representation of a method according to the disclosure for monitoring fault currents of such a PV energy generation plant.

### DETAILED DESCRIPTION

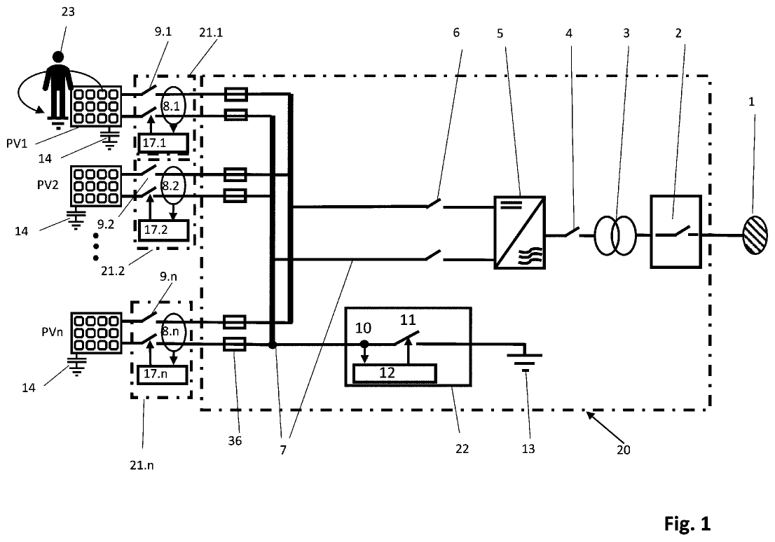

FIG. 1 shows an embodiment of a PV energy generation plant 1 according to the disclosure. The PV energy generation plant 1 comprises, as an embodiment of a direct current generator, a photovoltaic generator formed by a plurality of photovoltaic (PV) main strings PV1, PV2 . . . PVn. Each PV main string PV1 to PVn has a plurality of PV modules connected in series or a plurality of PV strings that in turn consist of a plurality of PV modules. The PV main strings PV1 to PVn are designed similarly, for example, identically, with regard to the number and type of PV modules. In addition, the PV main strings PVn are arranged close enough together that they are subject to at least similar ambient conditions with regard to irradiation and temperature. By way of example, a central inverter unit or circuit 20 is designed as a so-called multi-string inverter. For this purpose, it comprises at least as many DC inputs for DC lines as there are PV main strings PVn in the plant. The DC inputs are, in one embodiment, protected by pairs of fuses 36. The individual PV main strings PVn are connected in parallel to a common DC link circuit 7—for example, via DC busbars. This DC link circuit 7 can, for example, also be formed by a split DC link circuit with a center point. The common DC link circuit 7 is in turn connected to a DC side of a DC/AC converter 5 of the central inverter unit or circuit 20. In one embodiment, a DC isolating switch 6 is also provided, which can isolate the entire PV generator from the DC/AC converter 5 if necessary and prevent a power flow from the PV generator. By way of example, the AC side of the DC/AC converter 5, which in FIG. 1 is configured as a three-phase converter, is connected to a likewise three-phase alternating-voltage (AC) grid 1, e.g., a medium-voltage grid, via an AC isolating switch 4, a transformer 3, for example, a medium-voltage transformer, and a grid connection device 2. By way of example, a single-stage DC/AC converter 5 is shown. In the context of the disclosure, this can also be designed as a multi-stage converter—for example, with additional DC/DC stages not only unidirectional but also bidirectional. A controller (not shown) of the central inverter unit or circuit 20 controls the switches of the DC/AC converter 5 for the desired voltage conversion. Further components such as EMC filters and line filters are not shown for the sake of clarity. The PV plant, for example, the DC link circuit 7, is connected to a ground potential via a grounding connection 13. There is also galvanic isolation from the AC grid 1 via the transformer 3.

To monitor the central inverter unit or circuit 20 for a ground fault, a ground fault monitoring apparatus or circuit 22, a so-called GFDI (“ground fault detection and interruption”), is arranged in the grounded path between one pole of the DC link circuit 7 and the ground connection 13, and comprises a ground current measuring device or circuit 10, an isolating element or circuit 11, and a controller 12. The controller 12 is circuitry configured to trip the isolating element or circuit 11 after detecting a ground fault, which is detected when a ground current threshold value I_{S} of the current flow measured by the ground current measuring device or circuit 10 is exceeded. For example, the controller 12 of the ground fault monitoring apparatus or circuit 22 is configured to trip the isolating element or circuit 11 only after a defined delay time T.

The individual PV main strings PV1 to PVn have a parasitic capacitance 14 in relation to the ground potential, which can be different in each case. Discharge currents always flow in the direction of ground potential via the parasitic capacitances 14. These are capacitive reactive currents. The discharge currents, together with the parasitic capacitances 14, are dependent upon the ambient conditions of the PV strings such as humidity, temperature, precipitation, or the like. In some cases, they can change significantly over time, even if rather slowly over time. However, they change in a similar manner for the similar PV main strings PV1 to PVn.

In the event of a fault, e.g., if a grounded person 23 makes a contact between one of the PV modules, shown in FIG. 1 by way of example for PV main string PV1, and the ground potential, a fault current will flow across the person 23 toward the ground potential in addition to the discharge current on the PV string in which the fault was caused.

For the protection of persons 23 against electric shock, it must now be possible to detect sudden changes in current, such as those caused by the flow of life-threatening currents through the human body of persons 23. Such fault currents are already life-threatening at current levels that can be significantly below the typical current levels of non-hazardous capacitive discharge currents. For this reason, such PV energy generation plants may legally be operated only with (total) ground fault monitoring (GFDI) and in a secured electrical operating area, i.e., usually behind a fence. Fencing can only be dispensed with if the PV strings themselves are monitored for standardized values by means of an RCD.

Multiple monitoring units or circuits 21.1 to 21.n, so-called RCD's (“residual current detection and interruption”), are therefore provided to monitor critical fault currents that indicate faults in the region of the PV strings and their parallel connection. These each comprise a differential current measurement device or circuit 8.1 to 8.n, an isolating switch 9.1 to 9.n, and a monitoring controller 17.1 to 17.n, and are in each case assigned to the PV main strings PV1 to PVn. With the differential current measurement devices or circuits 8.1 to 8.n, the differential current I_{Diff} across a pair of DC lines of a PV main string PV1 to PVn is captured in each case. In the embodiment shown in FIG. 1, the monitoring units or circuits 21.1 to 21.n are formed externally, for example, in a connecting unit or combiner box in which individual PV modules or PV strings are interconnected to form a PV main string PVn and in which further monitoring and protection components can also be arranged. Alternatively, a monitoring unit or circuit 21.n can also be designed as part of the central inverter unit or circuit 20—for example, within a container housing of the central inverter unit or circuit 20, e.g., at each PV main string input of the central inverter unit or circuit 20.

Such monitoring, in one embodiment, can be reliably carried out via the differential current measurement devices 8.1 to 8.n when a current difference occurs on the two monitored lines of a PV main string PV1 to PVn. In order to detect the currents flowing away via the discharge capacitances 14 and, in case of a fault, via the grounded person 23, a return current path is employed. This return current path is implemented via the grounding connection 13. However, ground fault monitoring also takes place in the grounding connection 13, which causes the isolation to be tripped by means of the isolating element 11 and thus the grounding connection 13 to be interrupted. Furthermore, the entire energy generation plant is taken out of service—in the embodiment shown, for example, by tripping the DC main isolating switch 6. However, this prevents fault monitoring of the individual sub-generators. For this reason, the controller 12 of the ground fault monitoring apparatus or circuit 22 is configured to trip the isolating element or circuit 11 only after a defined delay time T, wherein the delay time T is selected to be greater than the reaction time T_{R} of the monitoring units or circuits 21.n, such that during the delay time T, the individual monitoring units or circuits 21.1 to 21.n have sufficient time to detect fault currents and, by means of their monitoring controllers 17.1 to 17.n, to trigger an isolation of the affected sub-generators PV.1 to PV.n by means of the isolating switch 9.1 to 9.n within their technical reaction time T_{R}.

As an example, a ground current fault is caused on the PV main string PV1 in FIG. 1. By means of the differential current measurement device or circuit 8.1, a sudden change in the usual discharge currents and/or a specified limit value being exceeded can now be detected. This signal is sent to the monitoring controller 17.1, which then opens the isolating switch 9.1 and isolates the faulty PV sub-generator PV1.

As an overcurrent protection device, a damping resistor (not shown) is provided on the ground fault monitoring apparatus or circuit 20 so that charging currents can flow for a sufficiently long time without damaging the components of the GFDI on the one hand, while on the other making it possible not to fall below the tripping time of the RCD in the event of a dangerous fault current occurring. The damping resistance is designed to be smaller than the total resistance of the PV generator, preferably less than 10%, and particularly preferably less than 1% of the total resistance of the PV generator. The differential current threshold value I_{S,Diff} of the monitoring unit or circuit 21.1 is, in one embodiment, less than or equal to 300 mA, and, in addition, sudden changes in the range of 30 to 150 mA are monitored. In this way, the damping resistance influences the overall resistance of the plant only very slightly and therefore has only a negligible influence on the efficiency of the PV plant.

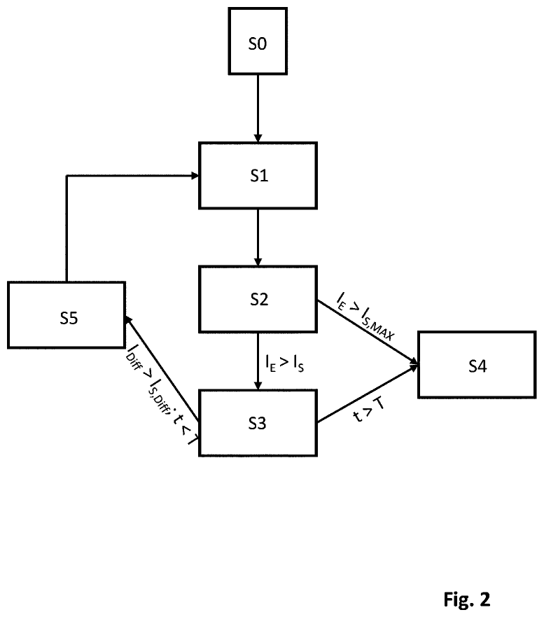

FIG. 2 shows a schematic procedure for monitoring fault currents in a PV energy generation plant according to the disclosure. During the commissioning of the PV energy generation plant, permanent fault current monitoring is also initiated via its overall control system (act S0).

In act S1, the ground current monitoring apparatus or circuit 22 permanently monitors the ground current I_{E} by means of its ground current measurement device or circuit 10, as described above. This measured ground current I_{E} is compared with ground current threshold values I_{S}. In one embodiment, this refers to several ground current threshold values, e.g., a minimum ground current threshold value I_{S,MIN}, the exceeding of which is equivalent to the detection of a ground current fault (act S2), and a maximum ground current threshold value I_{S,MAX}, which initiates further protective measures, as described below. The ground current monitoring apparatus or circuit 22 is configured to open the isolating element or circuit 11 by means of its controller 12 at act S4 after a ground current fault is detected at S2, i.e., after the minimum ground current threshold value I_{S,MIN} is exceeded by the measured ground current I_{E}, thus isolating the current path. The control unit 12 initiates a delay time T (step S3), only after which the isolating element 11 is tripped (step S4). The delay time T can be advantageously selected as a function of the level of the measured ground current I_{E}, but is selected to be longer than the typical technical reaction time T_{R} of the monitoring units or circuits 21.n. If, in the event of a fault, the comparison of the measured ground current I_{E} in act S2 shows that the measured ground current I_{E} is greater than a defined maximum ground current threshold value I_{S,MAX}, the isolating element or circuit 11 is tripped directly as an alternative to initiating the delay time T (act S4), or the defined delay time T is set to zero.

As with the ground current monitoring apparatus or circuit 22, the differential currents I_{Diff} of the individual main string lines are monitored in act S1 by the monitoring units or circuits 21.n using the differential current measuring devices or circuits 8.n. If these exceed a defined differential current threshold value I_{S,Diff}, the isolating switch 9.n is tripped by the monitoring controller 17.n of the relevant monitoring unit or circuit 21.n and the relevant main string is isolated (act S5). This part of the procedure is only possible during the triggered delay time T, because if the ground fault switch (isolating element or circuit 11) is tripped, the grounding connection 13 is isolated and therefore, due to the lack of a return current path, monitoring of the differential current by the monitoring unit or circuit would no longer be possible. If the measured ground current I_{E} of the ground current monitoring apparatus or circuit 22 also falls below the fault-inducing threshold value, the fault state is canceled and the delayed tripping of the isolating element or circuit 11 (ground fault switch) is suspended, allowing the monitoring system to return to the permanent monitoring state (act S1). Nevertheless, in a suitable manner, the plant controller can generate an error message that informs the user of the fault and enables the fault that has occurred in the disconnected sub-generator to be located.

What is claimed is:

1. A PV energy generation plant having a PV generator and a central inverter unit or circuit, wherein the PV generator comprises a plurality of PV main strings which are connected together in parallel and are connected, on an input side of the PV generator, to the central inverter unit or circuit via DC lines in each case, and are connected to an alternating voltage grid on an output side of the PV generator via a DC link circuit of the central inverter unit or circuit, and wherein the PV generator further comprises a DC/AC converter, an AC isolating switch, a transformer, and a grid connection circuit, wherein each pair of DC lines assigned to a respective PV main string of the plurality of PV main strings is assigned a monitoring circuit that comprises a differential current measurement circuit, an isolating switch, and a monitoring controller, wherein the monitoring controller is configured to open the isolating switch within a reaction time, after a differential current threshold value has been exceeded, in order to isolate the respective PV main string, and further comprising a ground fault monitoring circuit arranged between a pole of the DC link circuit and a grounding connection, wherein the ground fault monitoring circuit comprises a ground current measurement circuit, an isolating circuit, and a controller, wherein the controller of the ground fault monitoring circuit is configured to trip the isolating circuit after a defined delay time, after a ground fault has been detected by virtue of a ground current threshold value being exceeded, when the ground fault persists after elapse of the defined delay time, wherein the defined delay time is selected to be greater than the reaction time.

2. The PV energy generation plant according to claim 1, wherein the delay time is a value between and including 50 ms to 500 ms.

3. The PV energy generation plant according to claim 1, wherein a duration of the delay time depends upon a ground current measured by the ground current measurement circuit.

4. The PV energy generation plant according to claim 3, wherein a plurality of ground current threshold values are defined to which different delay times are assigned.

5. The PV energy generation plant according to claim 3, wherein the delay time is set to zero when a defined maximum ground current threshold value is exceeded.

6. The PV energy generation plant according to claim 1, wherein for the sole ground current threshold value, or, in a case of multiple ground current threshold values, a minimum ground current threshold value of the ground fault monitoring circuit is greater than or equal to 1A.

7. The PV energy generation plant according to claim 1, wherein the differential current threshold value of the monitoring circuit is less than or equal to 300 mA.

8. The PV energy generation plant according to claim 1, wherein the differential current measurement circuit is configured to detect changes in the differential current, in accordance with standard IEC 62109-2 or IEC 63112.

9. The PV energy generation plant according to claim 1, wherein the ground fault monitoring circuit has an overcurrent protection circuit.

10. The PV energy generation plant according to claim 9, wherein the overcurrent protection circuit comprises a damping resistor comprising a damping resistance.

11. The PV energy generation plant according to claim 10, wherein the damping resistance is smaller than a total resistance of the PV generator.

12. The PV energy generation plant according to claim 1, wherein the central inverter circuit or unit is configured to be operated with a modulation that does not impose clock-frequency common-mode voltages to ground on an AC voltage.

13. The PV energy generation plant according to claim 1, wherein the monitoring circuits are arranged on DC input lines of the PV main strings which are arranged within a housing of the central inverter unit or circuit and are thus part of the central inverter unit or circuit.

14. The PV energy generation plant according to claim 1, wherein the monitoring circuits are part of a connecting device that is assigned to each PV main string and that connects a plurality of PV strings to form a PV main string, wherein the connecting devices are arranged outside a housing of the central inverter unit or circuit.

15. A method for monitoring fault currents of a PV energy generation plant comprising a PV generator and a central inverter unit or circuit, wherein the PV generator comprises a plurality of PV main strings which are connected together in parallel and are connected, on an input side of the PV generator, to the central inverter unit or circuit via DC lines in each case, and are connected to an alternating voltage grid on an output side of the PV generator via a DC link circuit of the central inverter unit, and wherein the PV generator further comprises a DC/AC converter, an AC isolating switch, a transformer, and a grid connection circuit, wherein each pair of DC lines assigned to a respective PV main string of the plurality of PV main strings is assigned a monitoring circuit that comprises a differential current measurement circuit, an isolating switch, and a monitoring controller, wherein the monitoring controller is configured to open the isolating switch within a reaction time, after a differential current threshold value has been exceeded, in order to isolate the respective PV main string, and further comprising a ground fault monitoring circuit arranged between a pole of the DC link circuit and a grounding connection, wherein the ground fault monitoring circuit comprises a ground current measurement circuit, an isolating circuit, and a controller, wherein the controller of the ground fault monitoring circuit is configured to trip the isolating circuit after a defined delay time, after a ground fault has been detected by virtue of a ground current threshold value being exceeded, when the ground fault persists after elapse of the delay time, wherein the delay time is selected to be greater than the reaction time, the method comprising:
after the ground fault monitoring circuit detects a ground fault, tripping of the isolating switch is delayed by a defined delay time,
after detecting a differential current fault, using the monitoring controller of the monitoring circuit, opening the isolating switch within a reaction time, and
using the ground fault monitoring circuit tripping the isolating element when the ground fault persists after the defined delay time, wherein the delay time is selected to be greater than a reaction time of the monitoring circuit.
